(19) United States
(12) Patent Application Publication
(10) Pub. No.: US 2019/0181056 A1
(43) Pub. Date: Jun. 13, 2019

(54) SILICON-CONTAINING FILM ETCHING METHOD, COMPUTER-READABLE STORAGE MEDIUM, AND SILICON-CONTAINING FILM ETCHING APPARATUS

(71) Applicant: TOKYO ELECTRON LIMITED, Tokyo (JP)

(72) Inventors: Nobuhiro TAKAHASHI, Nirasaki City (JP); Koji TAKEYA, Nirasaki City (JP); Keiji TANOUCHI, Nirasaki City (JP)

(21) Appl. No.: 16/213,240

(22) Filed: Dec. 7, 2018

(30) Foreign Application Priority Data
Dec. 13, 2017 (JP) 2017-238355

(51) Int. Cl. H01L 21/66; H01L 21/3065; H01L 21/67

(52) U.S. Cl. CPC H01L 22/20; H01L 21/67069; H01L 21/3065

(57) ABSTRACT

There is provided a method of etching a silicon-containing film formed on a substrate, comprising: supplying an etching gas including a fluorine-containing gas having a smaller molecular weight than ClF₃ to the silicon-containing film; and controlling etching amounts at a central portion and an outer peripheral portion of the silicon-containing film by controlling a flow velocity of the etching gas.

### CROSS-REFERENCE TO RELATED APPLICATION

This application is based upon and claims the benefit of priority from Japanese Patent Application No. 2017-238355, filed on Dec. 13, 2017, the entire contents of which are incorporated herein by reference.

### TECHNICAL FIELD

The present disclosure relates to a method of etching a silicon-containing film formed on a substrate, a non-transitory computer-readable storage medium, and an apparatus of etching the silicon-containing film.

### BACKGROUND

In a semiconductor device, a film containing silicon is applied in a wide variety of applications. For example, a silicon germanium (SiGe) film or a silicon (Si) film is used for a gate electrode, a seed layer or the like. In a manufacturing process of a semiconductor device, the SiGe film or the Si film is formed on a substrate and is etched into a predetermined pattern.

Etching of a silicon-containing film such as a SiGe film or a Si film has been conventionally performed by various methods. For example, the SiGe film or the Si film is etched by exposing the SiGe film or the Si film to an etching gas containing F₂, HF, ClF₃ or HCl.

Depending on the state of a silicon-containing film which has been subjected to a previous process before an etching process, it may be necessary to control the in-plane distribution of an etching amount when etching the silicon-containing film. For example, when there is a deviation in the film thickness of the silicon-containing film subjected to the previous process, the in-plane uniformity of etching can be improved by controlling the in-plane distribution of an etching amount, for example, by increasing or decreasing an etching amount at the central portion of the silicon-containing film as compared to an etching amount at the outer peripheral portion thereof.

Similarly, even after performing a subsequent process followed by the etching process, it may be necessary to control the in-plane distribution of an etching amount depending on the state of the silicon-containing film. Particularly, along with the miniaturization of semiconductor devices in recent years, the pattern has also been miniaturized. Thus, such control of the etching amount is useful.

However, in the etching method of the related art, the state of the silicon-containing film which has been subjected to the previous process before the etching process or the subsequent process after the etching process is not taken into consideration. Therefore, there is room for improvement in the conventional silicon-containing film etching method.

### SUMMARY

Some embodiments of the present disclosure provide a technique of appropriately controlling the in-plane distribution of an etching amount of a silicon-containing film when etching the silicon-containing film formed on a substrate.

According to one embodiment of the present disclosure, there is provided a method of etching a silicon-containing film formed on a substrate, including: supplying an etching gas including a fluorine-containing gas having a smaller molecular weight than ClF₃ to the silicon-containing film; and controlling etching amounts at a central portion and an outer peripheral portion of the silicon-containing film by controlling a flow velocity of the etching gas.

According to another embodiment of the present disclosure, there is provided a non-transitory computer-readable storage medium storing a program that operates on a computer of a controller for controlling an etching apparatus such that the aforementioned method is performed by the etching apparatus.

According to another embodiment of the present disclosure, there is provided an apparatus of etching a silicon-containing film formed on a substrate, including: a chamber in which the substrate is accommodated; a gas supply part configured to supply an etching gas including a fluorine-containing gas having a smaller molecular weight than ClF₃ to the silicon-containing film; an exhaust part configured to discharge the etching gas inside the chamber; and a controller configured to control the gas supply part and the exhaust part, wherein the control part controls etching amounts at a central portion and an outer peripheral portion of the silicon-containing film by controlling a flow velocity of the etching gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view schematically showing the configuration of an etching apparatus according to an embodiment.

FIGS. 2A to 2C are explanatory views showing the verification results of an in-plane distribution of an etching amount when a flow rate of an etching gas including a ClF₃ gas and an Ar gas is changed.

FIGS. 3A to 3C are explanatory views showing the verification results of an in-plane distribution of an etching amount when a flow rate of an etching gas including an F₂ gas and an Ar gas is changed.

FIGS. 4A to 4D are explanatory views showing the verification results of an in-plane distribution of an etching amount when a flow rate of an etching gas including an F₂ gas is changed.

FIGS. 5A to 5C are explanatory views showing the verification results of an in-plane distribution of an etching amount when an etching gas including an F₂ gas and an Ar gas is used and an internal pressure of a chamber is changed.

FIGS. 6A to 6C are explanatory views showing etching states when an etching gas including an F₂ gas is used.

FIG. 7 is a graph showing a difference in incubation time between F₂ and ClF₃.

FIG. 8 is a graph showing a difference in reactivity between F₂ and ClF₃.

### DETAILED DESCRIPTION

Reference will now be made in detail to various embodiments, examples of which are illustrated in the accompanying drawings. In the subject specification and the drawings, elements having substantially the same functional configuration will be denoted by like reference numerals and redundant explanation will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

As a result of intensive investigation conducted by the present inventors, it was found that when etching a silicon-containing film, if an etching gas including a fluorine-containing gas having a smaller molecular weight than ClF₃ is used and if the etching gas is supplied to the silicon-containing film while controlling a flow velocity of the etching gas, it is possible to control etching amounts in the central portion and the outer peripheral portion of the silicon-containing film. That is to say, when a ClF₃ gas was used as the etching gas for the silicon-containing film, it was impossible to control the in-plane distribution of an etching amount of the silicon-containing film. The reason why the in-plane distribution of an etching amount can be controlled by controlling the flow velocity of the etching gas including the fluorine-containing gas will be described in detail in the embodiment described below.

### <Etching Apparatus>

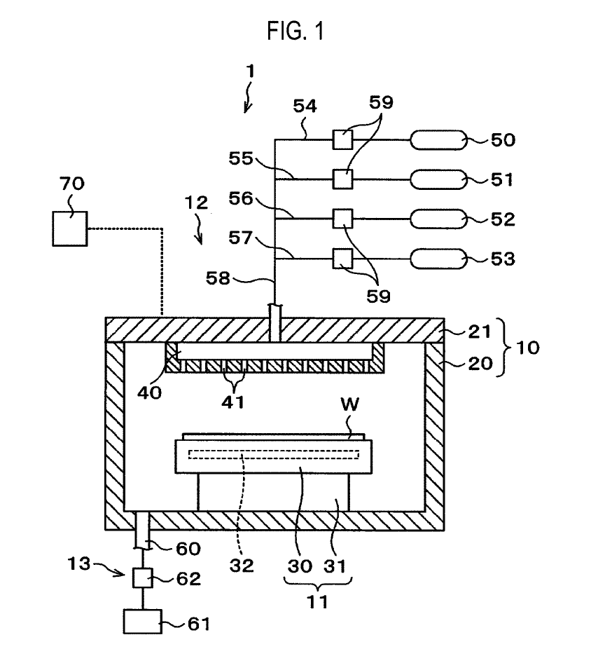

First, the configuration of the etching apparatus according to an embodiment of the present disclosure will be described. FIG. 1 is a vertical sectional view schematically showing the configuration of an etching apparatus 1 according to the present embodiment. In the present embodiment, a case where a silicon germanium (SiGe) film as a silicon-containing film formed on a wafer W as a substrate is etched in the etching apparatus 1 will be described. In addition, the etching performed in the etching apparatus 1 is a plasma-less gas etching.

As shown in FIG. 1, the etching apparatus 1 includes a chamber 10 in which the wafer W is accommodated, a mounting table 11 configured to mount the wafer W inside the chamber 10, a gas supply part 12 configured to supply a processing gas from above the mounting table 11 toward the mounting table 11, and an exhaust part 13 configured to discharge the processing gas existing in the chamber 10 therethrough.

The chamber 10 includes a chamber body 20 and a lid 21. An upper portion of the chamber body 20 is opened, and the opening is closed by the lid 21. A top surface of a side wall of the chamber body 20 and a lower surface of the lid 21 are hermetically sealed by a sealing material (not shown), whereby airtightness in the chamber 10 is secured. An airtight etching process space is defined inside the chamber 10. A loading/unloading port (not shown) for loading and unloading the wafer W therethrough is formed in the side wall of the chamber body 20. The loading/unloading port can be opened and closed by a gate valve (not shown).

The mounting table 11 includes an upper table 30 on which the wafer W is mounted and a lower table 31 fixed to a bottom surface of the chamber body 20 and configured to support the upper table 30. A temperature controller 32 for adjusting a temperature of the wafer W is provided inside the upper table 30. The temperature controller 32 adjusts a temperature of the mounting table 11 by circulating a temperature control medium such as, for example, water or the like and controls the temperature of the wafer W mounted on the mounting table 11 to a predetermined temperature.

The gas supply part 12 includes a shower head 40 configured to supply the processing gas to the wafer W mounted on the mounting table 11. The shower head 40 is provided on the lower surface of the lid 21 of the chamber 10 so as face the mounting table 11. A plurality of supply holes 41 for supplying the processing gas therethrough is formed in a lower surface (shower plate) of the shower head 40. The shower head 40 may have a diameter at least larger than that of the wafer W in order to uniformly supply the processing gas over the entire surface of the wafer W mounted on the mounting table 11.

In addition, the gas supply part 12 includes an F₂ gas supply source 50 for supplying an F₂ gas, an NH₃ gas supply source 51 for supplying an NH₃ gas, an HF gas supply source 52 for supplying an HF gas, and an Ar gas supply source 53 for supplying an Ar gas. An F₂ gas supply pipe 54 is connected to the F₂ gas supply source 50, an NH₃ gas supply pipe 55 is connected to the NH₃ gas supply source 51, an HF gas supply pipe 56 is connected to the HF gas supply source 52, and an Ar gas supply pipe 57 is connected to the Ar gas supply source 53. The supply pipes 54 to 57 are connected to a collective pipe 58 which is connected to the above-described shower head 40. The F₂ gas, the NH₃ gas, the HF gas and the Ar gas are supplied into the chamber 10 from the shower head 40 via the supply pipes 54 to 57 and the collective pipe 58.

Each of the F₂ gas supply pipe 54, the NH₃ gas supply pipe 55, the HF gas supply pipe 56 and the Ar gas supply pipe 57 is provided with a flow rate controller 59 for controlling the opening/closing operation of each of the supply pipes 54 to 57 and a flow rate of each of the processing gases. The flow rate controller 59 is constituted by, for example, an opening/closing valve and a mass flow controller.

Among the processing gases supplied from the gas supply part 12, the F₂ gas is an etching gas used for main etching. The NH₃ gas and the HF gas are used for removing a natural oxide film and terminating a film subjected to an etching process. The Ar gas is used as a dilution gas or a purge gas. Instead of the Ar gas, another inert gas such as an N₂ gas or the like may be used, or two or more inert gases may be used.

In the gas supply part 12 of the present embodiment, the processing gases are supplied from the shower head 40 to the wafer W. However, the method of supplying the processing gases is not limited thereto. For example, a gas supply nozzle (not shown) may be provided in the central portion of the lid 21 of the chamber 10, and the processing gases may be supplied from the gas supply nozzle.

The exhaust part 13 includes an exhaust pipe 60 installed outside the mounting table 11 and provided at the bottom of the chamber body 20 of the chamber 10. An exhaust mechanism 61 for evacuating the interior of the chamber 10 is connected to the exhaust pipe 60. An automatic pressure control valve (APC) 62 is provided in the exhaust pipe 60. An internal pressure of the chamber 10 is controlled by the exhaust mechanism 61 and the automatic pressure control valve 62.

The etching apparatus 1 is provided with a control part 70. The control part 70 is, for example, a computer, and includes a program storage part (not shown). In the program storage part, a program for controlling the etching process performed in the etching apparatus 1 is stored. The program may be recorded on a computer-readable storage medium such as a computer-readable hard disk (HD), a flexible disk (FD), a magneto-optical disk (MO), a memory card or the like and may be installed from the storage medium on the control part 70.

### <Etching Method>

Next, an etching method performed in the etching apparatus 1 configured as above will be described. As described above, in the etching apparatus 1 of the present embodiment, the SiGe film formed on the wafer W is etched.

First, in a state in which the gate valve is opened, the wafer W is loaded into the chamber 10 and mounted on the mounting table 11. The temperature of the mounting table 11 is controlled by the temperature controller 32, and the temperature of the wafer W mounted on the mounting table 11 is controlled to a predetermined temperature. Further, when the wafer W is mounted on the mounting table 11, the gate valve is closed to hermetically seal the interior of the chamber 10, whereby an etching process space is formed in the chamber 10.

Thereafter, the NH₃ gas and the HF gas are supplied into the chamber 10 while regulating the internal pressure of the chamber 10, whereby the natural oxide film formed on the wafer W is removed. At this time, in addition to the NH₃ gas and the HF gas, the Ar gas may be supplied as a dilution gas. In some embodiments, the NH₃ gas may be first supplied into the chamber 10 to stabilize the internal pressure and then the HF gas may be introduced into the chamber 10.

Thereafter, while supplying the Ar gas as a purge gas into the chamber 10, evacuation is performed to purge the interior of the chamber 10.

Thereafter, the F₂ gas is supplied as an etching gas into the chamber 10. At this time, the Ar gas may be added as a dilution gas. Then, the SiGe film on the wafer W is etched by the etching gas.

### <Etching Control>

In the etching apparatus 1, the SiGe film on the wafer W is etched as described above. Next, a method of controlling the in-plane distribution of an etching amount when etching the SiGe film will be described.

As a result of verification under various etching conditions, the present inventors have found that if a flow velocity of the etching gas including the F₂ gas is controlled when etching the SiGe film, it is possible to control etching amounts at the central portion and the outer peripheral portion of the SiGe film. The flow velocity of the etching gas referred to herein is a flow velocity of the etching gas supplied to the SiGe film inside the chamber 10. The control of the flow velocity of the etching gas is performed by controlling a flow rate of the etching gas supplied to the SiGe film inside the chamber 10 or the internal pressure of the chamber 10. Based on the verification results, the aforementioned findings will be described below.

In general, the F₂ gas or the ClF₃ gas is often used as the etching gas for the SiGe film. In the case of using the F₂ gas or the ClF₃ gas, the present inventors changed the flow rate of the etching gas and compared the in-plane distributions of an etching amount. The flow rate of the etching gas is controlled, for example, by the flow rate controller 59. In addition, the etching gas contains the Ar gas as a dilution gas. In the present verification, the flow rate of the etching gas as a whole was changed by changing the flow rate of the Ar gas. In the verification using the F₂ gas or the ClF₃ gas, the internal pressure of the chamber 10 is kept constant at 150 to 250 mT.

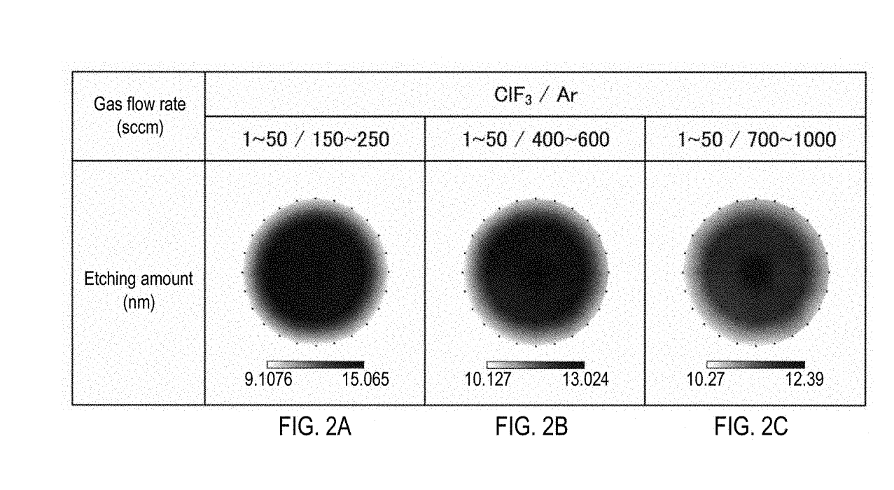

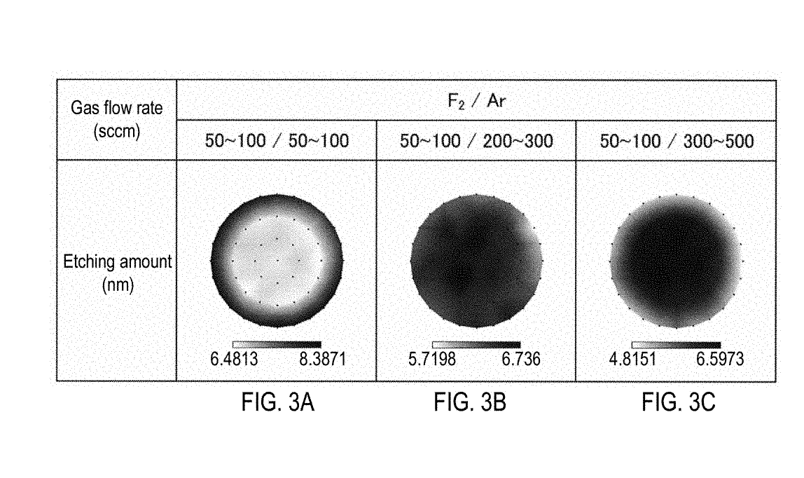

The results of this verification are shown in FIGS. 2A to 2C and 3A to 3C. FIGS. 2A to 2C show the verification results in the case of using the ClF₃ gas, and FIGS. 3A to 3C show the verification results in the case of using the F₂ gas.

As shown in FIGS. 2A to 2C, the flow rate of the ClF₃ gas was kept constant at 1 to 50 sccm, but the flow rate of the Ar gas was changed to 150 to 250 sccm, 400 to 600 sccm, and 700 to 1,000 sccm. In such a case, regardless of the flow rate of the etching gas, the etching amount at the central portion was larger than the etching amount at the outer peripheral portion, and there was no change in the tendency of the in-plane distribution of the etching amount. In other words, when the ClF₃ gas is used as the etching gas, it was not possible to control the in-plane distribution of the etching amount.

On the other hand, as shown in FIGS. 3A to 3C, the flow rate of the F₂ gas was kept constant at 50 to 100 sccm, but the flow rate of the Ar gas was changed to 50 to 100 sccm, 200 to 300 sccm, and 300 to 500 sccm. In such a case, as shown in FIG. 3A, when the flow rate of the etching gas is small, the etching amount at the outer peripheral portion was larger than the etching amount at the central portion. On the other hand, as shown in FIG. 3C, when the flow rate of the etching gas is relatively high, the etching amount at the central portion was larger than the etching amount at the outer peripheral portion. As shown in FIG. 3B, when the flow rate of the etching gas is intermediate, it was possible to make the etching amount substantially uniform in the plane. In this way, when the F₂ gas is used as the etching gas, it was possible to control the in-plane distribution of the etching amount by controlling the flow rate of the etching gas. It was also possible to improve the in-plane uniformity of etching.

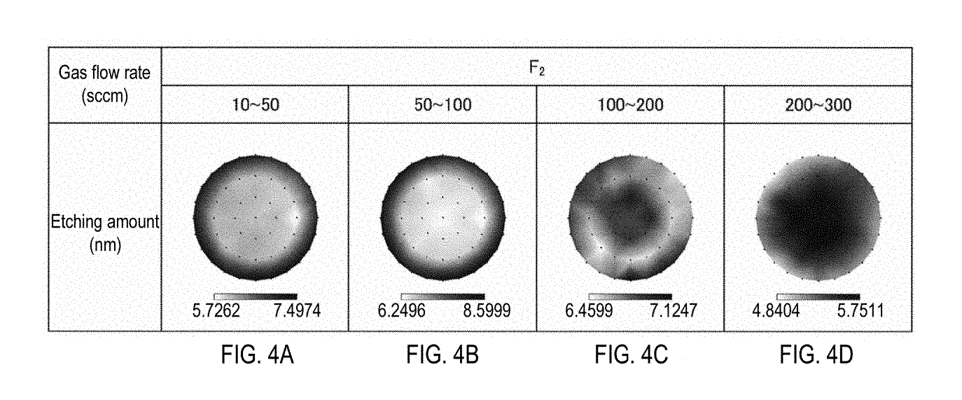

In the verification shown in FIGS. 3A to 3C, the Ar gas as a dilution gas is mixed with the etching gas. However, even when the F₂ gas alone is used as the etching gas as shown in FIGS. 4A to 4D, the same tendency was obtained. In the verification shown in FIGS. 4A to 4D, the flow rate of the F₂ gas was changed to 10 to 50 sccm, 50 to 100 sccm, 100 to 200 sccm, and 200 to 300 sccm. The internal pressure of the chamber 10 was kept constant at 50 to 200 mT.

As shown in FIGS. 4A and 4B, when the flow rate of the etching gas is small, the etching amount at the outer peripheral portion was larger than the etching amount at the central portion. On the other hand, as shown in FIG. 4D, when the flow rate of the etching gas is relatively high, the etching amount at the central portion was larger than the etching amount at the outer peripheral portion. As shown in FIG. 4C, when the flow rate of the etching gas is intermediate, it was possible to make the etching amount substantially uniform in the plane. Even when the F₂ gas alone is used as the etching gas in this manner, it was possible to control the in-plane distribution of the etching amount by controlling the flow rate of the F₂ gas.

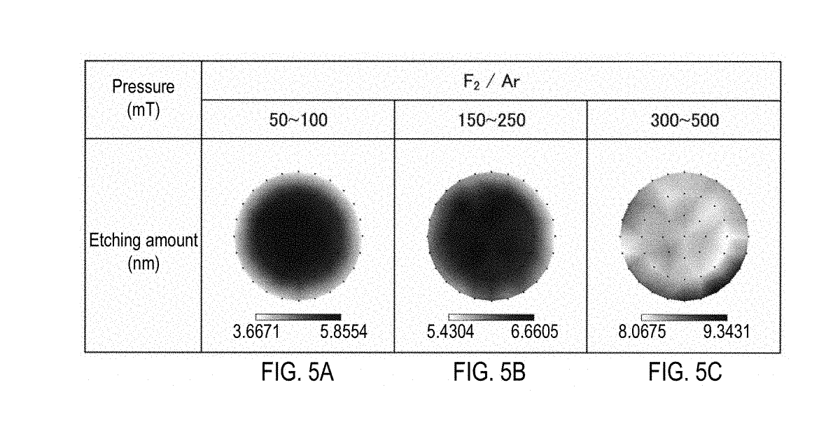

In the verification shown in FIGS. 3A to 3C, the in-plane distribution of the etching amount was controlled by controlling the flow rate of the etching gas. However, as shown in FIGS. 5A to 5C, even if the internal pressure of the chamber 10 is controlled, it was possible to control the in-plane distribution of the etching amount. In the verification shown in FIGS. 5A to 5C, the internal pressure of the chamber 10 is controlled by, for example, the exhaust mechanism 61 of the exhaust part 13 and the automatic pressure control valve 62. As shown in FIGS. 5A to 5C, the internal pressure of the chamber 10 was changed to 50 to 100 mT, 150 to 250 mT, and 300 to 500 mT. The flow rate of the F₂ gas as the etching gas was kept constant at 50 to 100 sccm, and the flow rate of the Ar gas was kept constant at 200 to 400 sccm.

As shown in FIG. 5A, when the internal pressure of the chamber 10 is relatively low, the etching amount at the central portion was larger than the etching amount at the outer peripheral portion. On the other hand, as shown in FIG. 5C, when the internal pressure of the chamber 10 is relatively high, the etching amount at the outer peripheral portion was larger than the etching amount at the central portion. As shown in FIG. 5B, when the internal pressure of the chamber 10 is intermediate, it was possible to make the etching amount substantially uniform in the plane. As described above, when the F₂ gas is used as the etching gas, it was possible to control the in-plane distribution of the etching amount by controlling the internal pressure of the chamber 10.

As described above, according to the verification results shown in FIGS. 2A to 5C, if the flow velocity of the etching gas including the F₂ gas (the flow rate of the etching gas or the internal pressure of the chamber 10) is controlled when etching the SiGe film, it is possible to control the etching amount at the central portion and the outer peripheral portion of the SiGe film.

### <Mechanism of Etching Control>

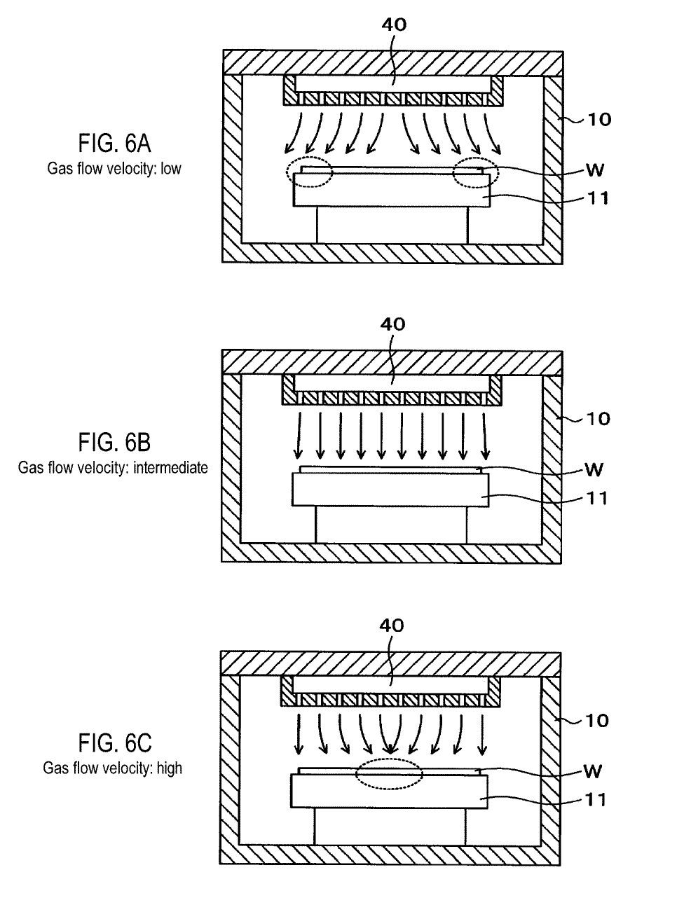

Next, a mechanism which controls the etching amounts at the central portion and the outer peripheral portion of the SiGe film by controlling the flow velocity of the etching gas including the F₂ gas in the aforementioned manner will be described. FIGS. 6A to 6C are explanatory views showing etching states when the F₂ gas is used as the etching gas.

FIG. 6A shows a case where the flow velocity of the etching gas is relatively low, the flow rate of the etching gas is relatively low, and/or the internal pressure of the chamber 10 is relatively high. In such a case, since the flow velocity of the etching gas is relatively low, there is a tendency for the etching gas to be pulled toward the exhaust part 13. For this reason, the F₂ gas is easily supplied to the outer peripheral portion of the SiGe film (portions indicated by dotted lines in FIG. 6A), but is less likely to be supplied to the central portion. As a result, the etching amount at the outer peripheral portion of the SiGe film is larger than the etching amount at the central portion.

On the other hand, FIG. 6C shows a case where the flow velocity of the etching gas is relatively high, the flow rate of the etching gas is relatively high, and/or the internal pressure of the chamber 10 is relatively low. In such a case, since the flow velocity of the etching gas is relatively high, there is a tendency that the etching gas is supplied to the SiGe film before being exhausted to the exhaust part 13. For this reason, the F₂ gas is easily supplied to the central portion (portion indicated by a dotted line in FIG. 6C) of the SiGe film, but is less likely to be supplied to the outer peripheral portion. As a result, the etching amount at the central portion of the SiGe film is larger than the etching amount at the outer peripheral portion.

FIG. 6B shows a case where the flow velocity of the etching gas is intermediate. In this case, the etching gas is supplied to the SiGe film substantially uniformly in the plane. As a result, the etching amount of the SiGe film can be made substantially uniform in the central portion and the outer peripheral portion.

As described above, the etching amounts at the central portion and the outer peripheral portion of the SiGe film vary depending on whether the flow velocity of the etching gas is high or low. This is because the molecular weight of the F₂ contained in the etching gas is at a low level of 38. That is to say, as will be described later, the F₂ has a small molecular weight, a long incubation time and a moderate reactivity. Therefore, the in-plane distribution of the etching amount varies depending on the flow velocity of the etching gas.

On the other hand, when the molecular weight of the F₂ is at a high level of 92.45 as in ClF₃, the etching gas is likely to be supplied to the central portion of the SiGe film regardless of the flow velocity of the etching gas. Therefore, in the case of using the etching gas including the ClF₃ gas, the etching amount at the central portion becomes larger than the etching amount at the outer peripheral portion. Thus, the in-plane distribution of the etching amount cannot be controlled.

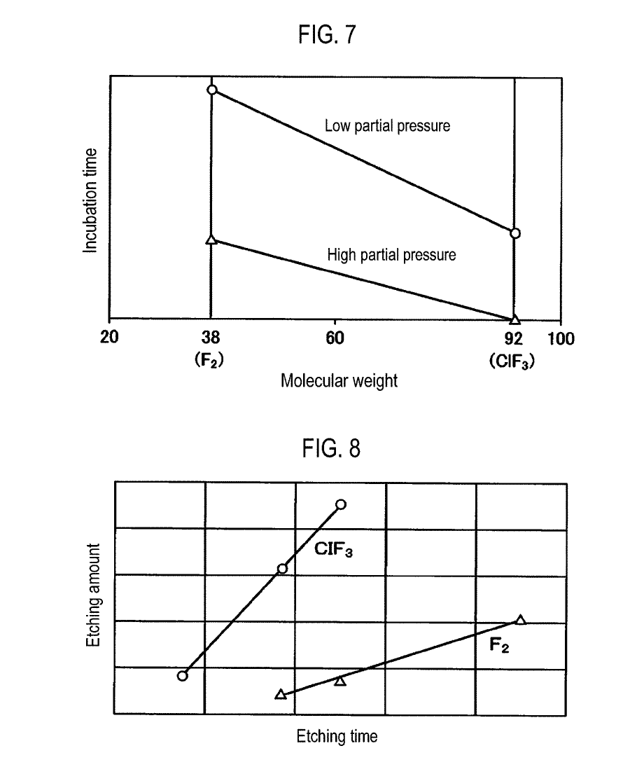

Further, as shown in FIG. 7, the incubation time of ClF₃ is shorter than that of F₂. The incubation time is a period of time from the supply of the etching gas to the start of etching. FIG. 7 is a graph showing a difference in incubation time between F₂ and ClF₃, in which the horizontal axis indicates the molecular weight and the vertical axis indicates the incubation time. Comparing F₂ and ClF₃, ClF₃ having a higher molecular weight is shorter in incubation time than F₂ having a lower molecular weight. In addition, this tendency does not depend on a partial pressure. The tendency remains the same regardless of whether the partial pressure is high or low. For this reason, in the case of the etching gas including the ClF₃ gas, ClF₃ reacts immediately with SiGe even if the flow velocity of the etching gas is changed. This makes it difficult to control the in-plane distribution of the etching amount.

Further, as shown in FIG. 8, ClF₃ is more reactive than F₂. FIG. 8 is a graph showing a difference in reactivity between F₂ and ClF₃, in which the horizontal axis indicates the etching time and the vertical axis indicates the etching amount. Comparing F₂ and ClF₃, the slope of the graph of ClF₃ is larger than that of F₂. That is to say, the reaction of ClF₃ is faster than that of F₂. Therefore, in the case of the etching gas including the ClF₃ gas, ClF₃ is likely to react with SiGe even if the flow velocity of the etching gas is changed. This makes it difficult to control the in-plane distribution of the etching amount.

As described above, ClF₃ has a larger molecular weight than F₂, and the incubation time of ClF₃ is relatively short due to the difference in molecular weight. Moreover, ClF₃ is more reactive than F₂. Therefore, in the case of the etching gas including the ClF₃ gas, it is difficult to control the in-plane distribution of the etching amount.

In other words, F₂ has a smaller molecular weight than ClF₃, and the incubation time of F₂ is relatively long due to the difference in molecular weight. In addition, the reactivity of F₂ is moderate. Therefore, in the case of using the etching gas including the F₂ gas, as shown in FIGS. 6A to 6C, it is possible to control the in-plane distribution of the etching amount.

Furthermore, as a result of investigation conducted by the present inventors, it was found that if the etching gas contains a fluorine-based gas having a smaller molecular weight than ClF₃, the incubation time becomes longer and the reactivity becomes moderate. For this reason, it is possible to obtain the same tendency as the tendency shown in FIGS. 6A to 6C in the in-plane distribution of the etching amount. Therefore, it is possible to control the in-plane distribution of the etching amount of the SiGe film by controlling the flow velocity of the etching gas containing the fluorine-based gas having a smaller molecular weight than ClF₃.

### <Application Example of Etching Control>

Next, application examples of the above etching control will be described. As the application examples, description will be made on a case where the etching control is applied to the setting of etching conditions (application example 1), a case where the etching control is applied to a feed-forward control based on the state of the silicon-containing film subjected to a previous process before etching (application example 2), a case where the etching control is applied to a feed-back control based on the state of the silicon-containing film subjected to a subsequent process followed by etching (application example 3), and a case where the etching control is applied to a feed-back control based on the state of the silicon-containing film immediately after etching (application example 4).

### Application Example 1

The etching condition setting of the application example 1 will be described. In the application example 1, first, an etching gas including an F₂ gas is supplied to a wafer Wc for etching condition setting to etch an SiGe film. The wafer Wc is not a product wafer W manufactured on an in-line basis but is a wafer used only for setting the etching conditions. Thereafter, the in-plane distribution of the etching amount of the etched SiGe film is measured. Any well-known method may be used for measuring the etching amount. Thereafter, based on the measurement result, the etching amount of the SiGe film is set in the plane so that the SiGe film after the etching has a desired size in the plane. The flow velocity of the etching gas is set based on this etching amount. For example, when it is desired to make an etching amount at the central portion of the SiGe film larger than an etching amount at the outer peripheral portion, the flow rate of the etching gas and the internal pressure of the chamber 10 are set so that the flow velocity of the etching gas becomes relatively high. Under the conditions thus set, the product wafer W is etched.

### Application Example 2

The feed-forward control of the application example 2 will be described. In the application example 2, the previous process before etching is performed on a wafer W manufactured on an in-line basis. Thereafter, immediately before the wafer W is loaded into the etching apparatus 1, the state of the SiGe film formed on the wafer W, for example, the film thickness of the SiGe film is measured. Any well-known method can be used for the measurement of the film thickness. Thereafter, the flow velocity of the etching gas is corrected based on the measurement result. For example, when the measurement result indicates that the film thickness at the central portion of the SiGe film is larger than the film thickness at the outer peripheral portion, the etching amount at the center portion is set larger than the etching amount at the outer peripheral portion in the etching process. In such a case, the flow rate of the etching gas and the internal pressure of the chamber 10 are set so that the flow velocity of the etching gas becomes relatively high. On the other hand, for example, when the measurement result indicates that the film thickness at the outer peripheral portion of the SiGe film is smaller than the film thickness at the central portion, the etching amount at the outer peripheral portion is set larger than the etching amount at the central portion in the etching process. In such a case, the flow rate of the etching gas and the internal pressure of the chamber 10 are set so that the flow velocity of the etching gas becomes relatively low. Then, the wafer W is etched under the corrected set conditions.

### Application Example 3

The feed-back control of the application example 3 will be described. In the application example 3, the subsequent process followed by etching is performed on a wafer W manufactured on an in-line basis, the state of the SiGe film formed on the wafer W, for example, the film thickness of the SiGe film is measured. Thereafter, the flow velocity of the etching gas is corrected based on the measurement result. For example, when the measurement result indicates that the film thickness at the central portion of the SiGe film is larger than the film thickness at the outer peripheral portion, the etching amount at the central portion is set larger than the etching amount at the outer peripheral portion in the etching process. In such a case, the flow rate of the etching gas and the internal pressure of the chamber 10 are set so that the flow velocity of the etching gas becomes relatively high. On the other hand, for example, when the measurement result indicates that the film thickness at the outer peripheral portion of the SiGe film is smaller than the film thickness at the central portion, the etching amount at the outer peripheral portion is set larger than the etching amount at the central portion in the etching process. In such a case, the flow rate of the etching gas and the internal pressure of the chamber 10 are set so that the flow velocity of the etching gas becomes relatively low. Then, a subsequent wafer W is etched under the corrected set conditions.

### Application Example 4

The feed-back control of the application example 4 will be described. In the application example 4, immediately after etching, the state of the SiGe film formed on the wafer W manufactured on an in-line basis, for example, the film thickness of the SiGe film is measured. Thereafter, the flow velocity of the etching gas is corrected based on the measurement result. For example, when it is desired to make the etching amount at the central portion of the SiGe film larger than the etching amount at the outer peripheral portion, the flow rate of the etching gas and the internal pressure of the chamber 10 are set so that the flow velocity of the etching gas becomes relatively high. On the other hand, for example, when it is desired to make the etching amount at the outer peripheral portion of the SiGe film larger than the etching amount at the central portion, the flow rate of the etching gas and the internal pressure of the chamber 10 are set so that the flow velocity of the etching gas becomes relatively low. Then, a subsequent wafer W is etched under the corrected set conditions.

### Other Embodiment

In the above embodiment, the etching control when etching the SiGe film has been described. However, the etching control of the present disclosure may also be applied to other silicon-containing films.

For example, when etching a silicon (Si) film, for example, a mixed gas of an F₂ gas and an NH₃ gas is used as the etching gas. The gas to be mixed with the F₂ gas is not limited to the NH₃ gas and may be any basic gas.

As in the above embodiment, it is possible to control the in-plane distribution of the etching amount of the Si film by controlling the flow velocity of the etching gas including the F₂ gas and the NH₃ gas. That is to say, by increasing the flow velocity of the etching gas, the etching amount at the central portion of the Si film can be made larger than the etching amount at the outer peripheral portion. Further, by lowering the flow velocity of the etching gas, the etching amount at the outer peripheral portion of the Si film can be made larger than the etching amount at the central portion. Since the mechanism of etching control of the Si film is similar to the mechanism of etching control of the SiGe film of the above embodiment, the detailed description thereof will be omitted.

According to the present disclosure in some embodiments, it is possible to appropriately control an in-plane distribution of an etching amount of a silicon-containing film by controlling a flow velocity of an etching gas including a fluorine-containing gas having a smaller molecular weight than ClF₃ when etching the silicon-containing film formed on a substrate.

Although the embodiment of the present disclosure has been described above, the present disclosure is not limited to this embodiment. Those having ordinary knowledge in the technical field to which the present disclosure belongs may clearly appreciate that various modifications or changes can be conceived within the scope of the technical idea described in the claims. It is understood that these modifications or changes fall within the technical scope of the present disclosure as well.

What is claimed is:

1. A method of etching a silicon-containing film formed on a substrate, comprising:
supplying an etching gas including a fluorine-containing gas having a smaller molecular weight than ClF₃ to the silicon-containing film; and
controlling etching amounts at a central portion and an outer peripheral portion of the silicon-containing film by controlling a flow velocity of the etching gas.

2. The method of claim 1, further comprising:
supplying the etching gas to the silicon-containing film formed on the substrate for setting an etching condition to etch the silicon-containing film;
subsequently, measuring an in-plane distribution of an etching amount of the etched silicon-containing film; and
subsequently, setting the flow velocity of the etching gas based on the measured in-plane distribution of the etching amount.

3. The method of claim 1, further comprising:
controlling the flow velocity of the etching gas based on a state of the silicon-containing film which has been subjected to an additional process performed separately from the etching of the silicon-containing film.

4. The method of claim 3, wherein the additional process is a process performed before the etching, and
the additional process includes feed-forward controlling the flow velocity of the etching gas based on the state of the silicon-containing film.

5. The method of claim 3, wherein the additional process is a process performed after the etching, and
the additional process includes feed-back controlling the flow velocity of the etching gas based on the state of the silicon-containing film.

6. The method of claim 1, wherein the step of controlling the flow velocity of the etching gas includes controlling a flow rate of the etching gas or an internal pressure of a processing space in which the etching is performed.

7. The method of claim 1, wherein the fluorine-containing gas has a molecular weight of 38 or less.

8. The method of claim 1, wherein the silicon-containing film is a silicon germanium film, and
the etching gas includes an F₂ gas for etching the silicon germanium film.

9. The method of claim 1, wherein the silicon-containing film is a silicon film, and
the etching gas includes an F₂ gas and a basic gas for etching the silicon film.

10. The method of claim 1, further comprising:
supplying the etching gas to the silicon-containing film from above the substrate; and
discharging the etching gas from a lateral side and a lower side of the substrate.

11. A non-transitory computer-readable storage medium storing a program that operates on a computer of a controller for controlling an etching apparatus such that the method of claim 1 is performed by the etching apparatus.

12. An apparatus of etching a silicon-containing film formed on a substrate, comprising:
a chamber in which the substrate is accommodated;
a gas supply part configured to supply an etching gas including a fluorine-containing gas having a smaller molecular weight than ClF₃ to the silicon-containing film;
an exhaust part configured to discharge the etching gas inside the chamber; and
a controller configured to control the gas supply part and the exhaust part,
wherein the control part controls etching amounts at a central portion and an outer peripheral portion of the silicon-containing film by controlling a flow velocity of the etching gas.
